(19) United States
(12) Patent Application Publication
(10) Pub. No.: US 2021/0003883 A1
(43) Pub. Date: Jan. 7, 2021

(54) PREPARATION METHOD OF BLACK MATRIX ON GLASS SUBSTRATE AND APPLICATION OF PREPARATION METHOD

(71) Applicant: SHENZHEN CHINA STAR OPTOELECTRONICS TECHNOLOGY CO., LTD., Shenzhen, Guangdong (CN)

(72) Inventor: Xue LIU, Shenzhen, Guangdong (CN)

(21) Appl. No.: 16/609,767

(22) PCT Filed: Aug. 27, 2019
(86) PCT No.: PCT/CN2019/102846

§ 371 Date: Oct. 31, 2019

(30) Foreign Application Priority Data
Jul. 2, 2019 (CN) 201910588275.4

(51) Int. Cl. G02F 1/1335; G02F 1/1333

(52) U.S. Cl. CPC G02F 1/133512; G02F 1/133305; G02F 1/133514

(57) ABSTRACT

A preparation method of a black matrix on a glass substrate and an application of the preparation method are provided. The method includes the following steps: Step S1, providing a glass substrate and forming a photoresist layer on the glass substrate by applying a photoresist; Step S2, forming a plurality of photoresist grooves on the photoresist layer; Step S3, filling the photoresist grooves with a black matrix photoresist; Step S4, exposing the black matrix photoresist to obtain the black matrix. The method may make a line width of the black matrix thinner, make a taper angle larger, and satisfy the requirement of high resolution, which improves aperture ratio of products. Furthermore, because steps of development process decrease in number and become simpler, the method is easy to be realized without difficulties. Therefore, occurrences of a small taper angle, undercut, and peeling phenomenon of the black matrix are reduced.

### FIELD OF INVENTION

The present invention relates to a display panel technology, and particularly relates to a preparation method of a black matrix on a glass substrate and an application of the preparation method.

### BACKGROUND OF INVENTION

Color filters (CF) of a thin-film-transistor liquid-crystal display (TFT-LCD) panel are formed with a plurality of pixels arranged in an array, and each pixel is composed of red (R), green (G), and blue (B) three subpixels. A black matrix is usually used for separating individual color pixels and preventing the color mixing between red, green, and blue pixels. With the development of pixel technology, the high-resolution (pixels per inch, PPI) display technology such as 8K and 16K have emerged, which requires increasing the number of pixels, reducing the pixel size, and devising a narrower line width of the black matrix used for separating the color filters. For satisfying the requirements of the high-resolution technology, a narrow-line-width black matrix also requires a larger taper angle to avoid decrease of the aperture ratio owing to a small taper angle.

Increasing the aperture ratio of the pixels has been pursued in the liquid crystal display industry. Many general techniques are utilized to increasing the aperture ratio. For example, copper wiring substitutes aluminum wiring to decrease the resistivity; techniques such as color filter on array (COA) or black matrix on array (BOA) is utilized to prevent a decrease of the aperture ratio owing to the displacement and the misalignment of the black-matrix light shielding region and the color filters. All these methods can increase the pixel the aperture ratio of the pixels, thereby achieving a high transmittance. Furthermore, preparing a black matrix with a narrow line width and a larger taper angle can not only satisfy the requirement of high resolution but also increase the aperture ratio to a certain extent, thereby increasing transmittance of a panel and reducing cost.

The black matrixes are mainly prepared by a lithography process in the conventional technology. First, applying a negative photoresist to form a film; then, using a photomask to proceed an exposure process, wherein the exposing portion is cured, does not react with the developer, and is retained after a development process; finally, proceeding a baking process to obtain a final pattern. However, due to the low resolution of the negative photoresist and the bottleneck of the process technology, the black matrixes so prepared have a wider line width and a smaller taper angle.

Therefore, to develop a new preparation method of a black matrix is required to overcome the deficiencies of the conventional technology.

### SUMMARY OF INVENTION

The present invention provides a preparation method of a black matrix on a glass substrate to solve the disadvantages in the conventional technology, namely, the black matrixes have a wider line width and a smaller taper angle.

For solving the above problems, the present invention provides a preparation method of a black matrix on a glass substrate. The method includes the following steps:

Step S1: providing a glass substrate and forming a photoresist layer on the glass substrate by applying a photoresist;

Step S2: forming a plurality of photoresist grooves on the photoresist layer;

Step S3: filling the photoresist grooves with a black matrix photoresist;

Step S4: exposing the black matrix photoresist to obtain the black matrix.

Further, in other embodiments, the photoresist in the Step S1 is a positive photoresist, and the photoresist grooves in the Step S2 are formed by a lithography process.

Further, in other embodiments, the photoresist in the Step S1 is a positive photoresist, and the photoresist grooves in the Step S2 are formed by a laser cutting process.

Further, in other embodiments, the photoresist in the Step S1 is a negative photoresist, and the photoresist grooves in the Step S2 are formed by a lithography process.

Further, in other embodiments, the photoresist in the Step S1 is a negative photoresist, and the photoresist grooves in the Step S2 are formed by a laser cutting process.

Further, in other embodiments, a shape of a cross-sectional of the photoresist groove is rectangular.

Further, in other embodiments, a width of the photoresist groove is less than 10 microns.

Further, in other embodiments, the black matrix photoresist in the Step S3 is filled into the photoresist grooves by an ink jet printing method.

For solving the above problems, the present invention provides a glass substrate. A black matrix is disposed on the glass substrate, and wherein the black matrix is formed by the preparation method according to the present invention.

Further, in other embodiments, a taper angle of the black matrix is 90 degrees.

Further, in other embodiments, a line width of the black matrix is less than 10 microns.

Compared with the conventional technology, the advantageous effects of the present invention are providing a preparation method of a black matrix on a glass substrate and an application of the preparation method to make a line width become less and a taper angle become larger. The black matrix so obtained satisfies the requirement of high resolution, and improves the aperture ratio of products; on the other hand, because the number of step for the development process is reduced, the preparation method is simple to operate without difficulties and easy to realize, and can reduce occurrences of a small taper angle, undercut, and peeling phenomenon of the black matrix.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a flowchart of a preparation method of a black matrix according to a first embodiment of the present invention.

FIG. 2 is a flowchart of a preparation method of a black matrix according to a second embodiment of the present invention.

FIG. 3 is a flowchart of a preparation method of a black matrix according to a third embodiment of the present invention.

FIG. 4 is a flowchart of a preparation method of a black matrix according to a fourth embodiment of the present invention.

### DETAILED DESCRIPTION OF PREFERRED EMBODIMENTS

Hereinafter, the present invention will be apparent technical solutions in the embodiments, fully described, obviously, the described embodiments are merely part of embodiments of the present invention rather than all embodiments. Based on the embodiments of the present invention, all other embodiments of ordinary skill in the art without any creative effort shall fall within the scope of the present invention.

The embodiments of the present disclosure are described in detail hereinafter. Examples of the described embodiments are given in the accompanying drawings, wherein the identical or similar reference numerals constantly denote the identical or similar elements or elements having the identical or similar functions. The specific embodiments described with reference to the attached drawings are all exemplary and are intended to illustrate and interpret the present disclosure, which shall not be construed as causing limitations to the present disclosure.

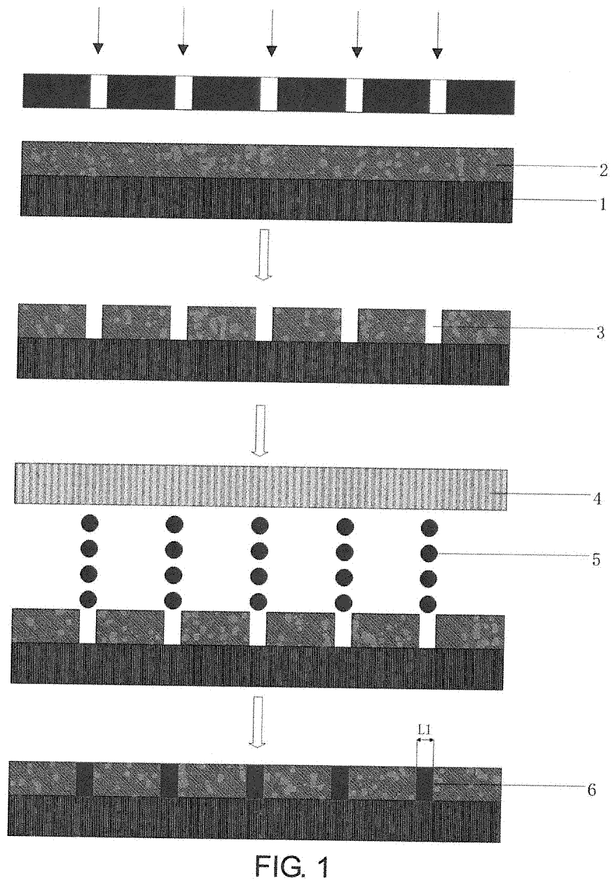

A first embodiment of the present disclosure provides a preparation method of a black matrix on a glass substrate. Please refer to FIG. 1, FIG. 1 is a flowchart of a preparation method of a black matrix according to the first embodiment. The method includes the following steps:

Step S1: providing a glass substrate 1 and applying a positive photoresist to form a photoresist layer 2 on the glass substrate 1.

In the conventional technology, a negative photoresist is applied when preparing a black matrix. However, due to the low resolution of the negative photoresist and the bottleneck of the process technology, the black matrixes so prepared have a wider line width and a smaller taper angle. In the first embodiment, a positive photoresist is applied when preparing a black matrix. Because the resolution of the positive photoresist is high, a narrow-line-width black matrix can be achieved.

Step S2: proceeding a lithography process and exposing the positive photoresist. The exposed region of the positive photoresist is lifted-off to obtain a plurality of photoresist grooves 3;

In the first embodiment, a shape of a cross-sectional of the photoresist groove 3 is rectangular. Preparing the photoresist grooves 3 ensures the line width of a black matrix photoresist achieves a narrow line width, and obtains a larger taper angle.

Step S3: by an ink jet printing method, the photoresist grooves are added dropwise a black matrix photoresist 5 from the nozzle of an inkjet printer 4;

Step S4: exposing the black matrix photoresist 5 to obtain a black matrix 6.

The first embodiment of the present disclosure further provides a glass substrate. A black matrix is disposed on the glass substrate, and wherein the black matrix is formed by the preparation method according to the first embodiment. The taper angle of the black matrix 6 so prepared is 90 degrees, and the line width L1 of the black matrix 6 so prepared is less than 10 microns.

In the conventional technology, a negative photoresist is applied to form a film. Then, a photomask is used for proceeding an exposure process. The exposing portion is cured, does not react with the developer, and is retained after a development process. Finally, a baking process is proceeded to obtain a final pattern.

In the first embodiment, after preparing the photoresist grooves 3 and adding dropwise a black matrix photoresist 5 into the photoresist grooves 3, the exposure process is the only process before obtaining the black matrix 6. The number of step for the development process is reduced in the preparation method. The preparation method is simple to operate without difficulties and easy to realize, and can reduce occurrences of a small taper angle, undercut, and peeling phenomenon of the black matrix during the development process.

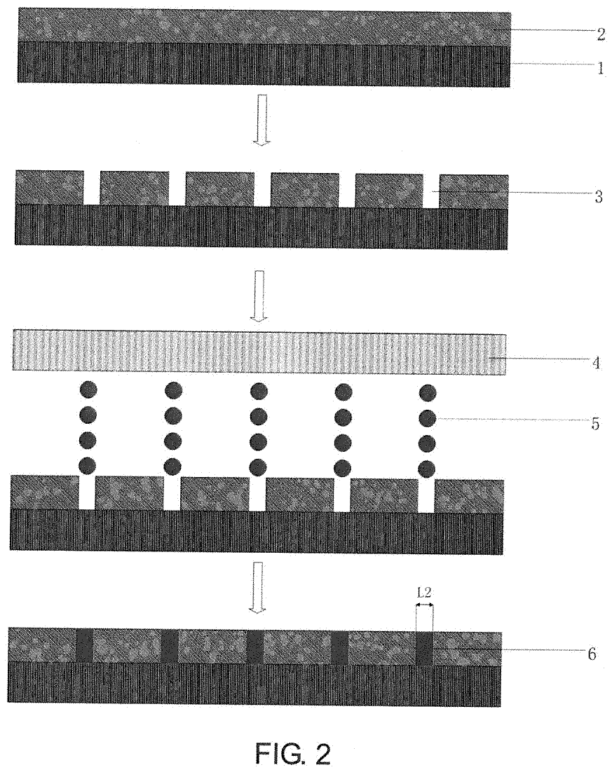

A second embodiment of the present disclosure provides a preparation method of a black matrix on a glass substrate. Please refer to FIG. 2, FIG. 2 is a flowchart of a preparation method of a black matrix according to the second embodiment. The method includes the following steps:

Step S1: providing a glass substrate 1 and applying a positive photoresist to form a photoresist layer 2 on the glass substrate 1.

In the conventional technology, a negative photoresist is applied when preparing a black matrix. However, due to the low resolution of the negative photoresist and the bottleneck of the process technology, the black matrixes so prepared have a wider line width and a smaller taper angle. In the second embodiment, a positive photoresist is applied when preparing a black matrix. Because the resolution of the positive photoresist is high, a narrow-line-width black matrix can be achieved.

Step S2: exposing the positive photoresist, and then precisely positioning and cutting by a laser to obtain a plurality of photoresist grooves 3;

In the second embodiment, a shape of a cross-sectional of the photoresist groove 3 is rectangular. Preparing the photoresist grooves 3 ensures the line width of a black matrix photoresist achieves a narrow line width, and obtains a larger taper angle.

Step S3: by an ink jet printing method, the photoresist grooves are added dropwise a black matrix photoresist 5 from the nozzle of an inkjet printer 4;

Step S4: exposing the black matrix photoresist 5 to obtain a black matrix 6.

The second embodiment of the present disclosure further provides a glass substrate. A black matrix is disposed on the glass substrate, and wherein the black matrix is formed by the preparation method according to the second embodiment. The taper angle of the black matrix 6 so prepared is 90 degrees, and the line width L2 of the black matrix 6 so prepared is less than 10 microns.

In the conventional technology, a negative photoresist is applied to form a film. Then, a photomask is used for proceeding an exposure process. The exposing portion is cured, does not react with the developer, and is retained after a development process. Finally, a baking process is proceeded to obtain a final pattern.

In the second embodiment, after preparing the photoresist grooves 3 and adding dropwise a black matrix photoresist 5 into the photoresist grooves 3, the exposure process is the only process before obtaining the black matrix 6. The number of step for the development process is reduced in the preparation method. The preparation method is simple to operate without difficulties and easy to realize, and can reduce occurrences of a small taper angle, undercut, and peeling phenomenon of the black matrix during the development process.

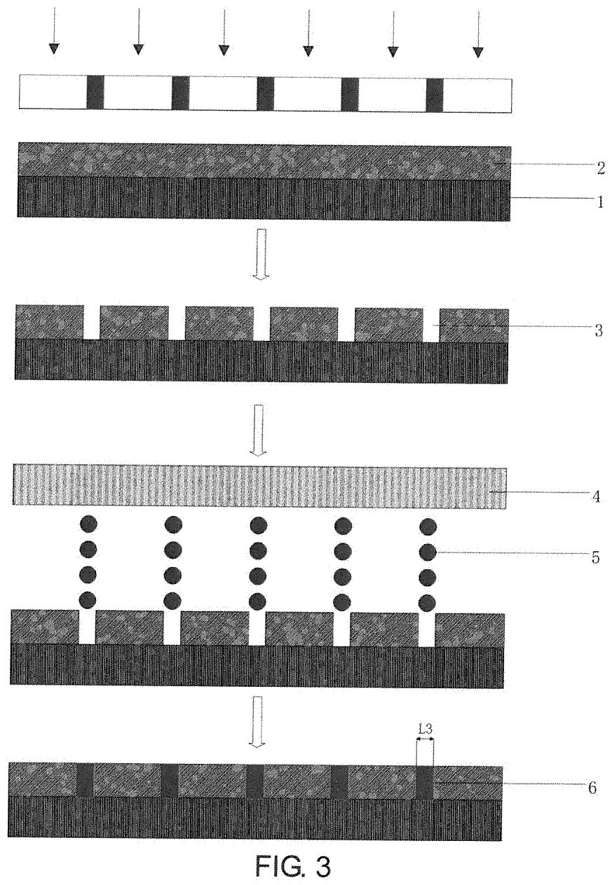

A third embodiment of the present disclosure provides a preparation method of a black matrix on a glass substrate. Please refer to FIG. 3, FIG. 3 is a flowchart of a preparation method of a black matrix according to the third embodiment. The method includes the following steps:

Step S1: providing a glass substrate 1 and applying a negative photoresist to form a photoresist layer 2 on the glass substrate 1.

Step S2: proceeding a lithography process and exposing the negative photoresist. The exposed region of the negative photoresist is retained to obtain a plurality of photoresist grooves 3;

In the third embodiment, a shape of a cross-sectional of the photoresist groove 3 is rectangular. Preparing the photoresist grooves 3 ensures the line width of a black matrix photoresist achieves a narrow line width, and obtains a larger taper angle.

Step S3: by an ink jet printing method, the photoresist grooves are added dropwise a black matrix photoresist 5 from the nozzle of an inkjet printer 4;

Step S4: exposing the black matrix photoresist 5 to obtain a black matrix 6.

The third embodiment of the present disclosure further provides a glass substrate. A black matrix is disposed on the glass substrate, and wherein the black matrix is formed by the preparation method according to the third embodiment. The taper angle of the black matrix 6 so prepared is 90 degrees, and the line width L3 of the black matrix 6 so prepared is less than 10 microns.

In the conventional technology, a negative photoresist is applied to form a film. Then, a photomask is used for proceeding an exposure process. The exposing portion is cured, does not react with the developer, and is retained after a development process. Finally, a baking process is proceeded to obtain a final pattern.

In the third embodiment, after preparing the photoresist grooves 3 and adding dropwise a black matrix photoresist 5 into the photoresist grooves 3, the exposure process is the only process before obtaining the black matrix 6. The number of step for the development process is reduced in the preparation method. The preparation method is simple to operate without difficulties and easy to realize, and can reduce occurrences of a small taper angle, undercut, and peeling phenomenon of the black matrix during the development process.

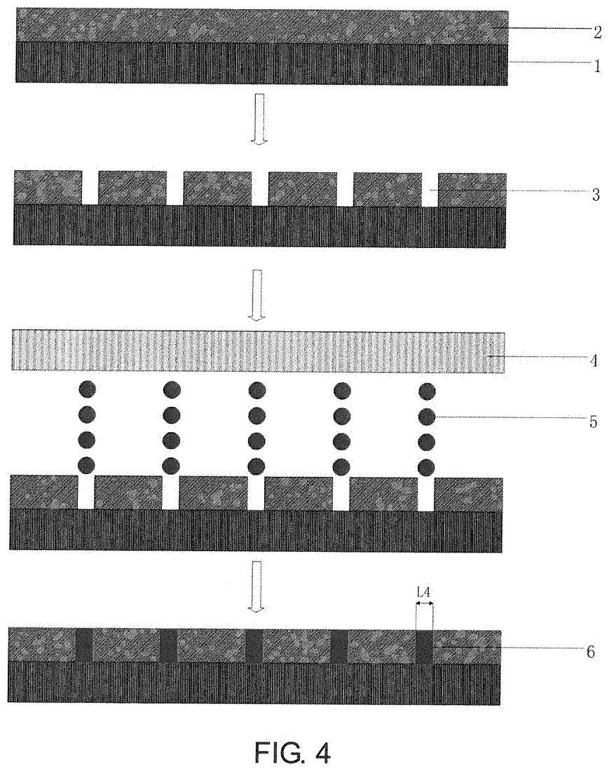

A fourth embodiment of the present disclosure provides a preparation method of a black matrix on a glass substrate. Please refer to FIG. 4, FIG. 4 is a flowchart of a preparation method of a black matrix according to the second embodiment. The method includes the following steps:

Step S1: providing a glass substrate 1 and applying a negative photoresist to form a photoresist layer 2 on the glass substrate 1.

Step S2: exposing the negative photoresist, and then precisely positioning and cutting by a laser to obtain a plurality of photoresist grooves 3;

In the fourth embodiment, a shape of a cross-sectional of the photoresist groove 3 is rectangular. Preparing the photoresist grooves 3 ensures the line width of a black matrix photoresist achieves a narrow line width, and obtains a larger taper angle.

Step S3: by an ink jet printing method, the photoresist grooves are added dropwise a black matrix photoresist 5 from the nozzle of an inkjet printer 4;

Step S4: exposing the black matrix photoresist 5 to obtain a black matrix 6.

The fourth embodiment of the present disclosure further provides a glass substrate. A black matrix is disposed on the glass substrate, and wherein the black matrix is formed by the preparation method according to the fourth embodiment. The taper angle of the black matrix 6 so prepared is 90 degrees, and the line width L4 of the black matrix 6 so prepared is less than 10 microns.

In the conventional technology, a negative photoresist is applied to form a film. Then, a photomask is used for proceeding an exposure process. The exposing portion is cured, does not react with the developer, and is retained after a development process. Finally, a baking process is proceeded to obtain a final pattern.

In the fourth embodiment, after preparing the photoresist grooves 3 and adding dropwise a black matrix photoresist 5 into the photoresist grooves 3, the exposure process is the only process before obtaining the black matrix 6. The number of step for the development process is reduced in the preparation method. The preparation method is simple to operate without difficulties and easy to realize, and can reduce occurrences of a small taper angle, undercut, and peeling phenomenon of the black matrix during the development process.

The above are only preferred embodiments of the present invention, it should be noted: to those of ordinary skill in the art, in the present invention without departing from the principles of the premise, can make various improvements and modifications, such modifications and modifications should also be regarded as the protection scope of the present invention.

1. A preparation method of a black matrix on a glass substrate, comprising the following steps:
Step S1: providing a glass substrate and forming a photoresist layer on the glass substrate by applying a photoresist;
Step S2: forming a plurality of photoresist grooves in the photoresist layer;
Step S3: filling the photoresist grooves with a black matrix photoresist; and
Step S4: exposing the black matrix photoresist to obtain the black matrix.

2. The preparation method according to claim 1, wherein the photoresist in the Step S1 is a positive photoresist, and the photoresist grooves in the Step S2 are formed by a lithography process.

3. The preparation method according to claim 1, wherein the photoresist in the Step S1 is a positive photoresist, and the photoresist grooves in the Step S2 are formed by a laser cutting process.

4. The preparation method according to claim 1, wherein the photoresist in the Step S1 is a negative photoresist, and the photoresist grooves in the Step S2 are formed by a lithography process.

5. The preparation method according to claim 1, wherein the photoresist in the Step S1 is a negative photoresist, and the photoresist grooves in the Step S2 are formed by a laser cutting process.

6. The preparation method according to claim 1, wherein a shape of a cross-sectional of the photoresist groove is rectangular.

7. The preparation method according to claim 1, wherein the black matrix photoresist in the Step S3 is filled into the photoresist grooves by an ink jet printing method.

8. A glass substrate, wherein a black matrix is disposed on the glass substrate, and wherein the black matrix is formed by the preparation method according to claim 1.

9. The glass substrate according to claim 8, wherein a taper angle of the black matrix is 90 degrees.

10. The glass substrate according to claim 8, wherein a line width of the black matrix is less than 10 microns.
